(19) United States
(12) Patent Application Publication
(10) Pub. No.: US 2025/0379041 A1
(43) Pub. Date: Dec. 11, 2025

(54) System and Method for Rapidly Establishing Steady State Vacuum Chamber Pressures

(71) Applicant: Yang Pan, SINGAPORE (SG)

(72) Inventor: Yang Pan, SINGAPORE (SG)

(73) Assignee: Inspiring Atoms Pte Ltd, SINGAPORE (SG)

(21) Appl. No.: 18/738,034

(22) Filed: Jun. 9, 2024

(51) Int. Cl. H01J 37/32; H01J 37/244

(52) U.S. Cl. CPC H01J 37/32834; H01J 37/244; H01J 37/32449; H01J 37/32981; H01J 2237/1825; H01J 2237/186; H01J 2237/24585; H01J 2237/3341

(57) ABSTRACT

This invention disclosure provides a semiconductor process system that rapidly establishes and maintains steady state vacuum chamber pressures. In one embodiment, the system achieves faster stabilization by fixing the set point for the vacuum valve and adjusting the chamber pressure using the driving currents for the solenoid valves of the Mass Flow Controllers (MFCs). In another embodiment, the system operates in training and inference modes. In the training mode, set points for the MFCs and the vacuum valve are determined using PID controls. These set points are then quickly deployed in inference mode during substrate processing, enabling efficient and consistent pressure control.

### FIELD OF THE INVENTION

The present invention pertains to semiconductor manufacturing, specifically to a system and method for quickly establishing steady state chamber pressures necessary for various process steps. This invention aims to improve chamber pressure control systems and methods, using atomic layer etching (ALE) as an example. The system and method are designed to reduce costs and enhance the efficiency of semiconductor manufacturing, including etching and deposition processes.

### BACKGROUND

Reactive ion etching (RIE) is a key technology in semiconductor manufacturing that uses various species, including neutrals, radicals, and ions, to influence the etching process. The synergistic interaction between ion and neutral fluxes significantly enhances the etching rate. However, modern etching processes, especially for high aspect ratio structures, face challenges in balancing these fluxes and achieving uniform results across 300 mm wafers.

Advanced processes such as ALE enable controlled material removal with atomic-level precision. The basic ALE process includes surface modification and material removal steps. Material removal can be achieved using thermal energy or kinetic energy from ions derived from inert gases. The versatility of ALE processes is demonstrated in various patents, including U.S. Pat. Nos. 10,208,383 and 10,727,073.

In semiconductor processing, it is standard practice to dynamically modulate multiple gases' flow rates using mass flow controllers (MFCs). Transitioning between process steps often requires establishing a steady state chamber pressure. A controller compares chamber pressure with target values and adjusts a vacuum valve's set point to modulate the extraction rate of byproducts and unconsumed gas. Proportional integral derivative (PID) control accelerates this convergence, but bulky vacuum valves can delay achieving steady state pressure, creating a bottleneck for various applications.

There is a clear need for innovations in semiconductor processes that streamline gas management, accelerate gas exchanges, reduce cycle time, and enhance the consistency of outcomes. This invention addresses these needs by introducing a novel system and method for quickly establishing steady state chamber pressure in a wide range of semiconductor process systems.

### SUMMARY

The present invention provides a process system for semiconductor manufacturing that incorporates innovative methods to rapidly establish and maintain steady state chamber pressures during substrate processing. The invention includes two primary embodiments, each offering significant improvements in process efficiency and cost-effectiveness.

In the first embodiment, the process system uses a fixed set point for the vacuum valve to control the extraction rate of gases and byproducts from the chamber. The chamber pressure is adjusted using the set points of MFCs. Solenoid valves in the MFCs, which move faster than the vacuum valve, enable quicker adjustments and thus improve the overall speed of establishing the steady state chamber pressure. The set points for the MFCs involve driving currents for the solenoid valve, allowing faster adjustment of the chamber pressure. Flow rates of the gases are variable against fixed constants as stipulated by a process recipe as a standard practice today in the industry.

The second embodiment introduces a process system capable of operating in training and inference modes. In the training mode, the system uses PID controls to determine the set points for the MFCs and the vacuum valve to achieve required chamber pressures stipulated from the process recipe. These set points are then stored in a storage unit. During the inference mode, used for actual substrate processing, the system retrieves and deploys the stored set points to quickly achieve the required chamber pressure. This method bypasses the slower PID adjustment phase, leveraging pre-determined values to expedite the process. The set points include the driving currents for the solenoid valves of the MFCs and the driving current for an actuator of the vacuum valve, ensuring that the system can quickly and accurately reach the desired pressure levels.

The present invention enhances the overall efficiency and affordability of semiconductor manufacturing processes. The system's ability to quickly adjust to desired pressures and maintain stability throughout the processing cycle significantly improves the speed and reliability of semiconductor fabrication.

### BRIEF DESCRIPTIONS OF DRAWINGS

For enhanced clarity, the following description refers to accompanying drawings:

FIG. 1: Depicts a conventional ALE process system.

FIG. 2: Depicts an embodiment of the ALE process system of the present invention.

FIG. 3: Represents a functional diagram of an MFC.

FIG. 4A: Displays a flowchart detailing the steps of the first embodiment for establishing a steady state chamber pressure.

FIG. 4B: Shows a flowchart detailing the steps of the second embodiment for establishing a steady state chamber pressure.

FIG. 5: Highlights the sequence of the ALE process by employing the first embodiment.

FIG. 6: Showcases another embodiment of the ALE process system.

### DETAILED DESCRIPTIONS

To provide a thorough understanding, this description elaborates on embodiments of the present invention. While specific details are outlined for clarity, adaptations and variations consistent with the subsequent claims are considered acceptable. Selected conventional methods and components are described to emphasize the unique aspects of the invention.

The ALE process system is employed to elaborate on the inventive concepts of fast gas delivery and swift chamber pressure establishment for a vacuum-based plasma process. However, the inventive concept can be readily applied to any process systems or chambers. The use of the ALE process system is exemplary and should not limit the scope of the present inventive concept. For example, the present inventive concept can be applied to any type of etching and deposition process system, either plasma-based or thermal-based.

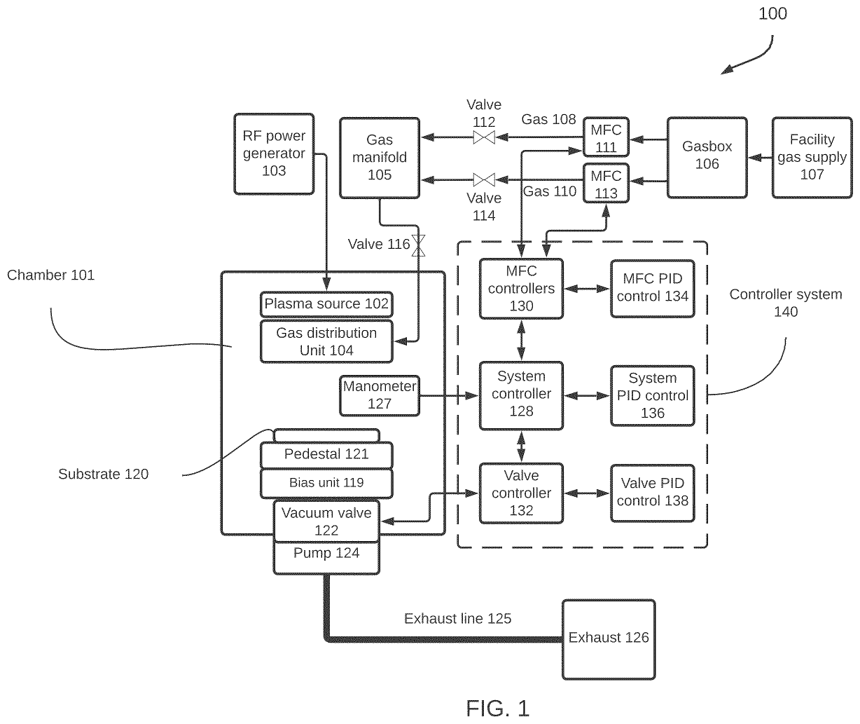

FIG. 1 illustrates a conventional ALE process system, labeled as 100. Housed within a vacuum setting, the chamber 101 is equipped with a plasma source 102, powered by its associated RF power generator 103. The plasma source 102 can adopt various designs, including transformer coupled plasma (TCP) and inductively coupled plasma (ICP). Some implementations might include a matching network (not shown) positioned between the RF power generator 103 and plasma source 102, while others might directly connect the two.

In the configuration presented in FIG. 1, a gas delivery system is depicted including a gas distribution unit 104, a gasbox 106, a gas manifold 105, MFCs (111 and 113), and valves (112, 114, and 116). The gas distribution unit 104 draws gases from the gasbox 106 through the gas manifold 105. Based on specific design needs, this unit 104 might take the form of a showerhead or an injector. The manifold 105 combines various gases prior to their introduction to the chamber 101. Valves 112 and 114 are located between the gasbox 106 and the manifold 105 to control the flow of a first gas 108 and a second gas 110, respectively. It's important to clarify that, although only two gas lines are illustrated for clarity, multiple gases could participate in ALE processes. The first gas 108, or similarly the second gas 110, may be a single gas or a mix of various gases. Another valve 116, situated between the manifold and the distribution unit 104, governs the gas flow into the chamber 101. The gasbox 106 is connected to a facility gas supply 107. MFCs 111 and 113 are optionally placed in the gas lines to control flow rates for the gases 108 and 110, respectively. In some implementations, the MFCs are integrated with the gasbox 106.

Inside the chamber 101, a pedestal 121 provides support for the substrate 120. This pedestal often resembles an electrostatic chuck (ESC), crafted specifically for etching tasks. To guarantee the desired ion energy-especially vital for etching high aspect ratio structures—a bias unit 119 is activated once plasma forms in the chamber. The bias unit can either be an RF power generator linked to the pedestal 121 via a blocking capacitor or a tailored waveform generator, depending on the design parameters.

To remove gases and resultant byproducts from chamber 101, a pump 124 is utilized. A vacuum valve 122, adjacent to this pump, adjusts the evacuation speed, guiding the gases towards an exhaust 126 via an exhaust line 125. Maintaining a consistent pressure within the chamber involves a balancing act between gas input and output rates. This equilibrium is achieved by a controller system 140.

In the conventional operation of the process system 100, a process recipe is provided to the system controller 128. The process recipe typically includes flow rates for the gases and required chamber pressures for various process steps, such as the surface modification step and the sputtering step in the ALE process.

The flow rate of the gases can be established by MFC controllers 130 employing MFC PID control 134. Each MFC comprises its own controller and PID control.

The flow rate for the extraction of unreacted gases and resultant byproducts inside chamber 101 is determined by the capacity of the pump 124 and the set point of the vacuum valve 122. In one implementation, the size of the valve opening determines its extraction rate, which can be controlled by a valve controller 132 through an actuator by varying the driving current to the actuator. A valve PID control 138 is used to achieve a final set point for the vacuum valve 122.

To achieve a steady state chamber pressure, the system controller 128 applies system PID control 136. After the gas or gases are introduced into the chamber 101, a manometer 137 measures the chamber pressure periodically and sends the measured results to the system controller 128. The system controller 128 compares the received results with the required chamber pressure from the recipe. If there is a discrepancy, the system controller 128 will direct the valve controller 132 to adjust the set point of the vacuum valve 122 until the required steady state chamber pressure is established. In conventional implementations, the flow rates of the incoming gases remain unchanged after they achieve the values required by the process recipe. Hence, the adjustment of the flow rate is mainly a local operation to the MFC controllers 130. However, to achieve the steady state chamber pressure, the system controller 128 is required to work with the valve controller 132. This operation involves both valve PID control 138 and system PID control 136. The process to achieve the steady state chamber pressure could take hundreds of milliseconds, which is not fast enough for advanced ALE or atomic layer deposition (ALD) processes.

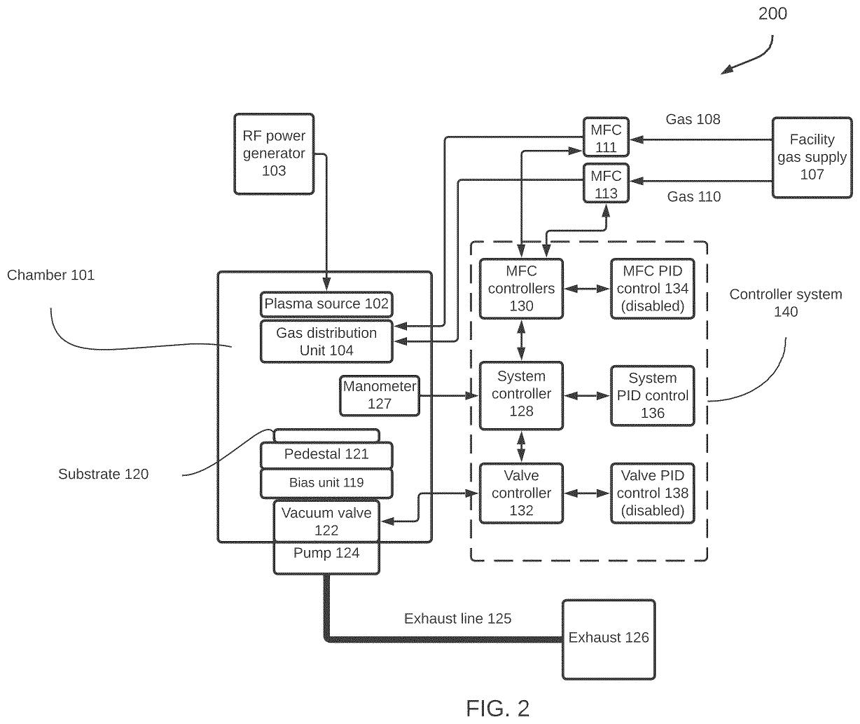

FIG. 2 illustrates an embodiment of an improved ALE process system, designated as system 200. The system 200 demonstrates a significant simplification from system 100 by eliminating various components. This exemplary system 200 comprises a chamber 101 for a vacuum-based process. System 200 may adopt diverse forms, all of which necessitate maintenance at a steady-state chamber pressure. For clarity, the ALE process system using two gases serves as a representative example to elucidate the innovative concept.

The system 200 incorporates a gas distribution unit 104 that sources gas 108 from a facility gas supply 107 via MFC 111 and gas 110 through MFC 113. Uniquely, the MFCs operate in such a manner that they can function both as a flow rate regulator and a valve. Furthermore, the PID controls, typically associated with the MFCs, are intentionally deactivated. These PID control loops are denoted as MFC PID control 134. The driving currents for the solenoid valves determine the positions of the plungers related to an orifice which define the conductance of a gas-conducting channel in an MFC.

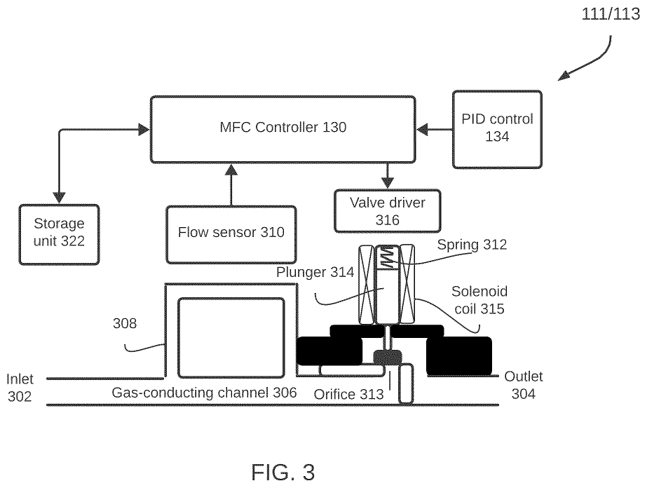

In the schematic representation of an exemplary MFC 111 or MFC 113 in FIG. 3, the MFC comprises an inlet 302 and an outlet 304, both connected via a gas-conducting channel 306. A proportional valve, not depicted in the figure, diverts a portion of the gas to a channel 308. The diverted gas's flow rate is determined by the flow sensor 310, typically employing thermal sensing to measure the temperature differences at two designated positions along a flow path. This flow rate acts as a proxy for the overall flow rate in the gas-conducting channel 306. The MFC 300 features a solenoid valve. This valve comprises a spring 312 that holds a plunger 314 in place. The position of the plunger 314 determines the gas conductance across orifices 313. When the plunger obstructs the channel within orifice 313, gas flow stops. The solenoid coil 315 controls the position of the plunger. When current flows through the coil, it creates a magnetic force, which, combined with the force exerted by the spring 312, determines the position of the plunger 314.

In conventional operation, the flow sensor 310 sends its readings to the MFC controller 130. The controller compares the flow rate data to a benchmarked value in its storage unit 322, corresponding to a desired gas flow rate. If discrepancies arise between the measured flow rate and the target, the MFC controller 130 instructs the valve driver 316 to adjust the current in solenoid coil 315, thereby changing the plunger's position 314. This calibration loop continues until the measured flow rate matches the target. To expedite the process, the MFC controller 318 uses PID control. This process can take several dozen to several hundred milliseconds.

The MFC 111 or MFC 113 can be operated in a training mode or in an inference mode. In the training mode, the MFC controller 130 conducts a test procedure to determine the driving currents for the solenoid valves for the first and second gases at required flow rates stipulated by an ALE process recipe. The determined current values are stored in storage unit 322, coupled to the MFC controller 130.

In a novel application, the MFC controller 130 switches the MFCs to their inference mode immediately after a process in the chamber 101 is initiated. The PID control 134 is deactivated accordingly, significantly reducing the MFC's operational time. Instead of the longer adjustment phase seen in training mode, the MFCs deliver the desired gas flow rate in a few milliseconds or less in inference mode. The MFC controller 130 retrieves the stored value of the driving current for the solenoid valve from the storage unit 322. Applying currents to solenoid coil 315 quickly sets the plunger 314 to the correct positions.

In some embodiments, the driving current for the solenoid valve is controlled directly by the system controller 128. The PID control 134 is bypassed. The driving current for the solenoid valve becomes a variable in the PID control 136. The system controller adjusts the value of the driving current for the solenoid valve to achieve the required steady state chamber pressure by dynamically measuring the chamber pressure with the manometer 127.

The ALE process system 200 integrates a pump designed to evacuate gases and byproducts resulting from chemical reactions in the chamber, channeling them to exhaust 126 via exhaust line 128. Positioned atop pump 118 is a vacuum valve 116, which governs the rate of extraction. This vacuum valve 116 can assume multiple configurations including, but not limited to, a pendulum valve, a butterfly valve, a combo valve, and a poppet valve. The range of pumps, like pump 118, spans options such as dry pumps, diffusion pumps, cryopumps, and turbomolecular pumps. In some embodiments, the set point for the vacuum valve 122 is fixed. The system controller 128 adjusts the driving current for the solenoid valve of the MFCs to achieve steady state chamber pressure without changing the conductance of the vacuum valve 122, as determined by the set point for its actuator.

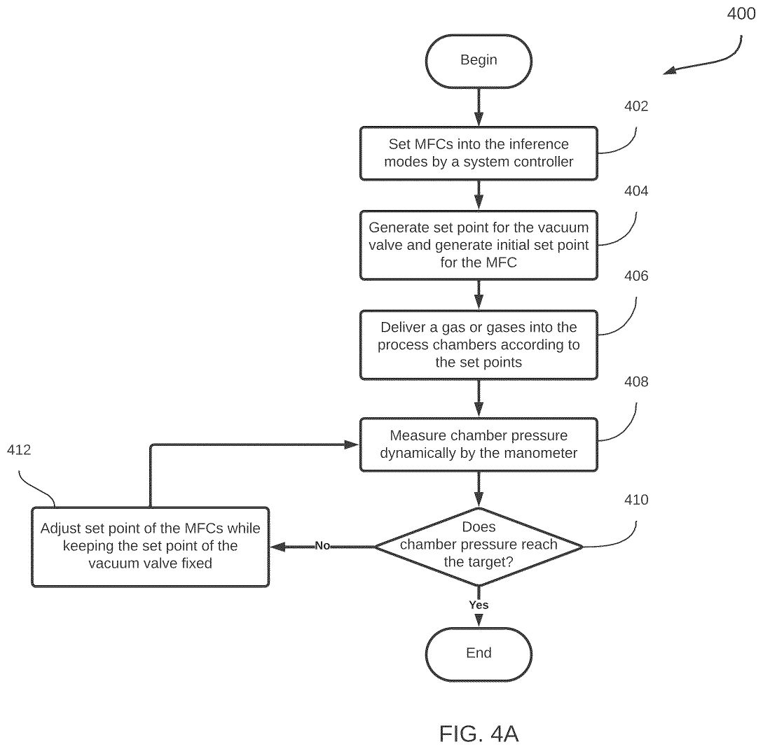

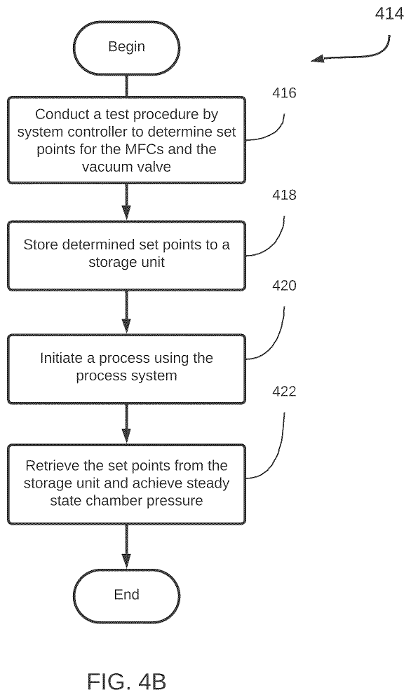

FIG. 4A illustrates a flowchart for the operations of system 200 in the first embodiment. Process 400 starts with step 402, where the MFCs are set into inference mode by deactivating their PID control 134.

In step 404, the set point for the vacuum valve 122 is generated by the system controller 128. The set point may be determined by a model or by leveraging historical data of the valve's operations. Simultaneously, the initial set points for the MFCs are generated, which may be adjusted during the operation to establish steady state chamber pressure. The initial set points of the MFCs may also be determined from a model or based on historical data of their operations.

In step 406, a gas or a mix of gases is delivered into the chamber by utilizing the MFCs operated according to the set points. In step 408, the chamber pressures are measured by the manometer 127 at a predetermined frequency periodically.

In step 410, the system controller 128 reviews the data from the manometer and decides if the steady state pressure has been achieved, meeting the requirements of the process recipe. If so, the process 400 ends. Otherwise, the set point (driving current for the solenoid valve) is adjusted in step 412 according to a PID algorithm, and the process repeats from step 408.

In the second embodiment, as shown in FIG. 4B, the ALE system 200 can be operated in a training mode or in an inference mode. The set points for the MFCs and the valve 122 are determined through a test procedure while operating the ALE process system 200 in the training mode.

Process 414 starts with step 416. During a test procedure conducted by the system controller 128, the system 200 operates with all PID controls (134, 136, and 138) activated. After the chamber pressure reaches the steady state required by the process recipe, the set points, including the driving currents for the solenoid valve for the MFCs and the set point for the actuator for the vacuum valve 122, are measured.

In step 418, the set points are stored in a storage unit (not shown in the Figures) of the system controller 128. The set points may also be stored in a local storage unit like 322 for the MFCs. After a process in the chamber 101 is initiated in step 422, the system controller 128 retrieves the set points from the storage unit and brings the MFCs and the vacuum valve to the required state for the process. The manometer 127 may be used to monitor if the steady state is reached without adjusting the set points.

In some implementations, the manometer may be used to measure the chamber pressures and store the measurements in the storage unit of the system controller 128. The data may be used to generate a trend chart for the pressure at one of the multiple steps of the process recipe. The system controller 128 may initiate a re-training event if any trend is out of control according to a set of predetermined statistical process control (SPC) rules.

In certain implementations, the flow rates of the MFCs are modified in a proportional manner. This means that when multiple MFCs are operational, flow rate adjustments occur at uniform percentages. In alternative setups, the flow rate of an individual or select MFCs may be adjusted. In other configurations, distinct MFCs undergo differential adjustments based on a pre-established protocol.

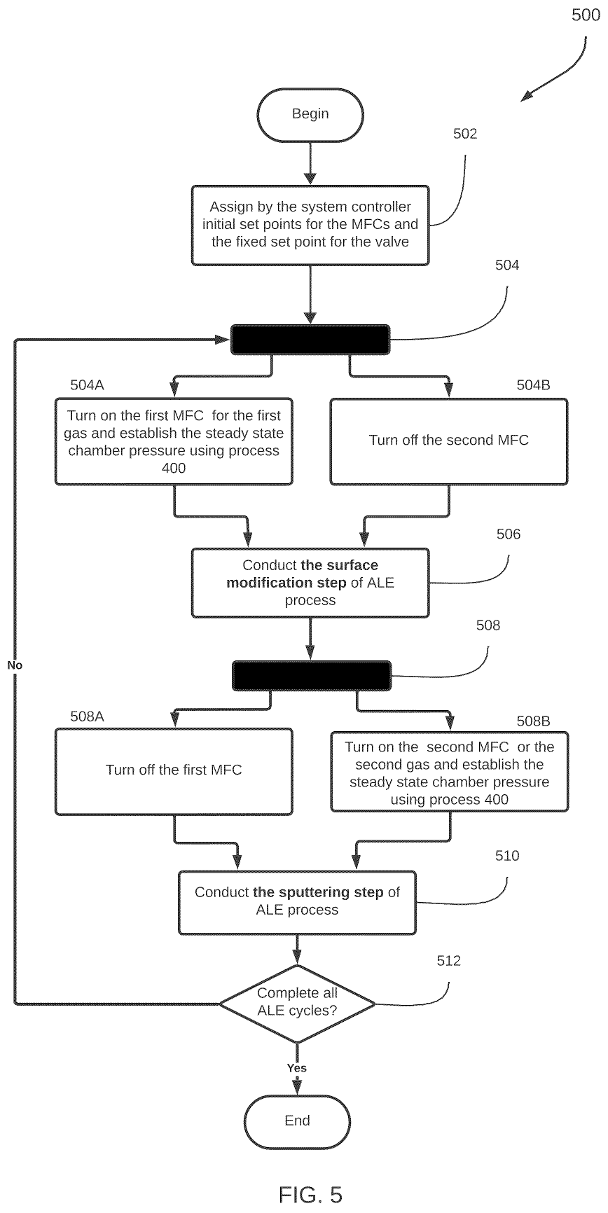

FIG. 5 elucidates an exemplary ALE process flow 500 for utilizing the process system 200. Beginning with step 502, before starting the ALE process, the system controller 128 assigns the initial set points to the MFCs (111 and 113) and the set point to the vacuum valve 122. The set point for the vacuum valve 122 is fixed during the ALE process. The PID controls (134, 138) for the MFCs and for the valve are deactivated.

Moving to step 504, it branches into two parallel actions: 504A and 504B. In 504A, the first MFC is turned on for the first gas through the execution of process 400A or 400B. As a result, a steady state chamber pressure is established, ready for a surface modification step of the ALE process. Concurrently, in step 504B, the second MFC is turned off to stop the second gas channel into the chamber.

The surface modification step is conducted in step 506. During the surface modification step, the plasma source 102 in chamber 101 receives RF power from the RF power generator 103. Neutrals created in the plasma in the chamber diffuse to the surface of the substrate and react with the atoms in the surface to form a modified layer with weakened bonds.

Next, in step 508, there are two simultaneous actions: 508A and 508B. In 508A, the first MFC reduces the flow rate of the first gas to zero. In contrast, in 508B, the second MFC is turned on and the steady state chamber pressure for the sputtering step is obtained by running process 400A or 400B again.

These two parallel operations (508A and 508B) can either be initiated at the same time or, in some implementations, a short delay might be introduced between them to ensure that the first gas is fully cleared from the chamber before the second gas is introduced.

Following this, step 510 represents the sputtering step of the ALE process. Here, the altered surface layer is removed due to the action of energetic ions produced by the plasma and the bias unit. This completes one round of the ALE process.

Lastly, in step 512, the system controller 128 checks the number of ALE cycles completed and determines whether to initiate another cycle based on the process recipe's requirements.

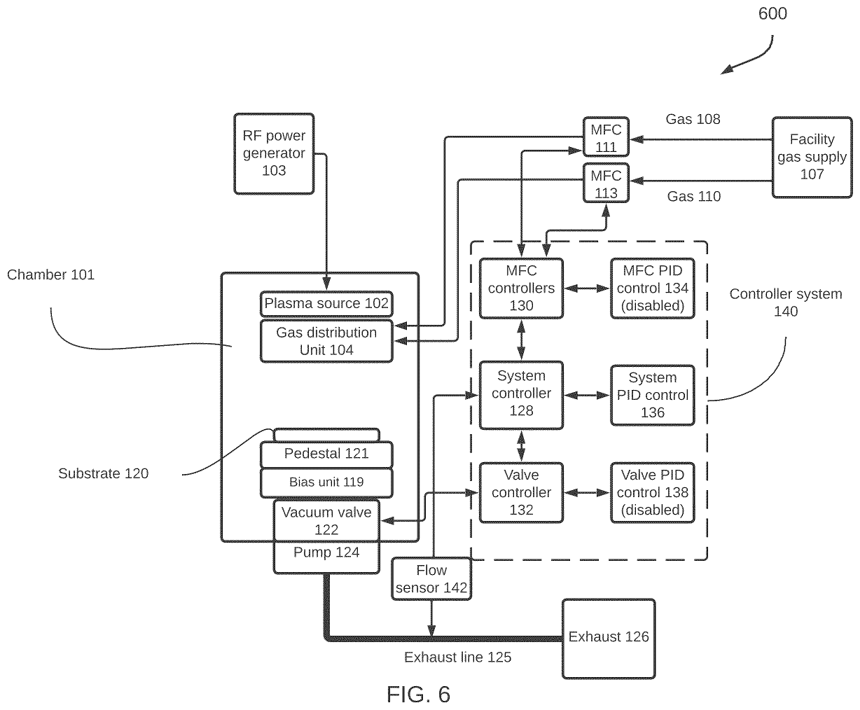

FIG. 6 showcases another embodiment of the system, denoted as 600. The difference between system 600 and system 200 is that the manometer 127 is eliminated. Instead, a flow sensor 142 coupled to the exhaust line 125 is employed to measure flow rate downstream. The system controller 128 uses the measured flow rate from the flow sensor 142 to gauge if a steady state chamber pressure has been achieved. This embodiment helps to reduce overall system cost because the manometer 127 is an expensive part.

1. A process system for semiconductor manufacturing, comprising:
a chamber configured to operate within a vacuum environment;
a pedestal structured to support a substrate during processing;
a pump designed to remove gases and byproducts from the chamber;
a vacuum valve coupled to the pump, wherein its set point determines the extraction rate of the gases and the byproducts;
a plurality of MFCs equipped with solenoid valves and MFC PID controls, wherein the MFCs operate with the MFC PID controls deactivated during substrate processing; and
a system controller for obtaining a steady state chamber pressure through a system PID control, achieved by periodically gauging if the chamber pressure has reached a steady state by a sensor and adjusting at least one of the currents for the solenoid valves of the MFCs while the set point of the vacuum valve is fixed.

2. The system of claim 1, wherein the vacuum valve is coupled to a valve PID control, which is deactivated during the processing of the substrate.

3. The system of claim 1, wherein the system further includes a simplified gas delivery system bypassing a gasbox.

4. The system of claim 1, wherein the solenoid valves further include coils for receiving the currents dictated by the MFC controllers or the system controller.

5. The system of claim 1, wherein the sensor further includes a manometer inside the chamber.

6. The system of claim 1, wherein the sensor further includes a flow sensor coupled to an exhaust line.

7. The system of claim 1, wherein the set point for the vacuum valve further includes a driving current for an actuator of the vacuum valve.

8. The system of claim 1, wherein the process system further includes etching or deposition process systems.

9. The system of claim 8, wherein the etching and deposition process systems further include plasma enhanced or thermal process systems.

10. A process system for semiconductor manufacturing, comprising:
a chamber configured to operate within a vacuum environment;
a pedestal structured to support a substrate during processing;
a pump designed to remove gases and byproducts from the chamber;
a vacuum valve coupled to the pump, wherein its set point determines the extraction rate of gases and byproducts from the chamber;
a plurality of MFCs equipped with solenoid valves and PID controls; and
a system controller for operating the process system in a training mode or an inference mode, wherein in the training mode, set points for the MFCs and the vacuum valve for achieving a required chamber pressure are determined and stored in a storage unit, wherein in the inference mode, the set points are retrieved and deployed by the system controller to obtain the required chamber pressure, wherein a substrate is processed while the process system is operated in the inference mode.

11. The system of claim 10, wherein the vacuum valve is coupled to a valve PID control, which is deactivated during the processing of the substrate.

12. The system of claim 10, wherein the MFCs are operated with deactivated MFC PID controls during the processing of the substrate.

13. The system of claim 10, wherein the system controller achieves the required chamber pressure involving a system PID control.

14. The system of claim 13, wherein the system PID control further includes a sensor.

15. The system of claim 14, wherein the sensor further includes a flow sensor coupled to an exhaust line.

16. The system of claim 10, wherein the set point for the vacuum valve further includes a driving current for an actuator of the vacuum valve and the set points for the MFCs further include the currents for the solenoid valves.

17. An ALE process, comprising the following steps:
a. assigning by a system controller initial set points for a first and a second MFC and a fixed set point for a vacuum valve, wherein the vacuum valve is operated with a pump for withdrawing gases and byproducts from a chamber;
b. turning on the first MFC for a first gas and turning off the second MFC for the second gas, wherein the system controller establishes a steady state chamber pressure by adjusting the set point of the first MFC;
c. conducting a surface modification step of the ALE process;
d. turning on the second MFC for the second gas and turning off the first MFC for the first gas, wherein the system controller establishes a steady state chamber pressure by adjusting the set point of the second MFC;
e. conducting a sputtering step of the ALE process; and
f. repeating steps a to e until the ALE process is completed.

18. The method of claim 17, wherein the set points for the MFCs further include driving current for solenoid valves.

19. The method of claim 17, wherein the fixed set point for the vacuum valve further includes a driving current for an actuator of the vacuum valve.

20. The method of claim 17, further including a step of measuring the chamber pressure by a manometer and storing the measurement results in a storage unit, wherein the system controller utilizes the results to monitor the stability of the chamber pressure according to SPC rules.
